(19) United States
(12) Patent Application Publication
(10) Pub. No.: US 2025/0063848 A1
(43) Pub. Date: Feb. 20, 2025

(54) Cadmium Selenide Based Photovoltaic Devices And Methods For Forming The Same

(71) Applicant: First Solar, Inc., Tempe, AZ (US)

(72) Inventors: Tursun Ablekim, San Jose, CA (US); Sachit Grover, Campbell, CA (US); James Hack, Sunnyvale, CA (US); Elline Hettiaratchy, Santa Clara, CA (US); Taylor Hill, Fort Collins, CO (US); Sergei Kniajanski, Perrysburg, OH (US); Wyatt Metzger, San Jose, CA (US); Nicholas Valdes, Los Altos, CA (US); Gang Xiong, Santa Clara, CA (US)

(73) Assignee: First Solar, Inc., Tempe, AZ (US)

(21) Appl. No.: 18/723,069

(22) PCT Filed: Dec. 23, 2022
(86) PCT No.: PCT/US2022/053972

§ 371 Date: Jun. 21, 2024

Related U.S. Application Data
(60) Provisional application No. 63/293,347, filed on Dec. 23, 2021.

(51) Int. Cl. H01L 31/0368; H01L 31/0296; H01L 31/18

(52) U.S. Cl. CPC H01L 31/0368; H01L 31/02963; H01L 31/1828

(57) ABSTRACT

Provided are photovoltaic devices with polycrystalline type II-VI semiconductor absorber materials including n-type absorber compositions and having p-type hole contact layers are described herein. Methods of treating semiconductor absorber layers and forming hole contact layers are described.

### BACKGROUND

A photovoltaic device generates electrical power by converting light into direct current electricity using semiconductor materials that exhibit the photovoltaic effect. The photovoltaic effect generates electrical power upon exposure to light as photons are absorbed within the semiconductor material to excite electrons to a higher energy state. These excited electrons are thus able to move within the material, thereby causing current.

Thin film photovoltaic devices are typically made of various layers of different materials, each serving a different function, formed on a substrate. A thin film photovoltaic device includes a front electrode and a back electrode to provide electrical access to the photoactive semiconductor layer or to other layers that are sandwiched there-between.

Despite many improvements developed for ever increasing conversion efficiencies, there remains a continuing need for improved thin film PV devices that minimize absorption losses while capturing or recovering the maximum amount of solar radiation practicable.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, wherein like reference numerals designate identical or corresponding parts throughout the views. The patent or application file may contain at least one drawing executed in color and/or one or more photographs. Copies of this patent or patent application publication with color drawings will be provided by the Patent Office upon request and payment of the necessary fee.

FIG. 1 schematically depicts a cross-sectional view of a tandem photovoltaic device according to one or more embodiments shown and described herein.

FIG. 2 schematically depicts an example submodule of the photovoltaic device of FIG. 1 according to one or more embodiments shown and described herein.

FIG. 3A, FIG. 3B, and FIG. 3C schematically depict a cross-sectional view along 3-3 of the photovoltaic submodule of FIG. 2 according to one or more embodiments described herein.

FIG. 4 schematically depicts a substrate according to one or more embodiments shown and described herein.

FIG. 5 schematically depicts a cross-sectional view of the tandem photovoltaic device of FIG. 1 according to one or more embodiments shown and described herein.

FIG. 6 schematically depicts a cross-sectional view of a layer stack according to one or more embodiments shown and described herein.

FIG. 7 depicts an example method according to one or more embodiments shown and described herein.

FIG. 8 depicts transient curves of time-resolved photoluminescence intensity (TRPL) for CdSe layers produced according to described methods.

FIG. 9A, FIG. 9B, and FIG. 9C depict images of a treated layer.

FIG. 10 depicts a contour chart showing a log of ratio of fractional grain orientation as assessed from electron back scattered diffraction (EBSD) and illustrating crystal orientation produced from selected deposition and treatment conditions.

FIG. 11 shows measurements of O— and O2- normalized to Se— as measured by time of flight secondary ion mass spectroscopy (TOF-SIMS).

FIG. 12 shows images of Cl— as measured by TOF-SIMS in a sample of a treated film.

FIG. 13 shows images of O— as measured by TOF-SIMS in a sample of a treated film.

FIG. 14 shows a comparison of photoluminescence spectrum for films treated with Se and without Se.

FIG. 15 depicts transient curves of time-resolved photoluminescence intensity (TRPL) for CdSe layers produced with and without Se treatment.

FIG. 16 depicts carrier density vs. depletion width derived from capacitance-voltage measurements for CdSe layers produced with and without Se treatment.

FIG. 17 depicts changes in x-ray florescence spectroscopy counts before and after CHT treatment for CdSe layers produced with and without Se treatment.

FIG. 18 illustrates changes in apparent charge carrier density concentration in films corresponding to treatment processes.

### DETAILED DESCRIPTION

Provided are structures and compositions for use in photovoltaic (PV) devices. Embodiments provide absorber layers including or consisting essentially of cadmium selenide.

Cadmium selenide (CdSe) layers can be formed by physical vapor deposition techniques. These deposition techniques can produce as-deposited polycrystalline films having grain sizes smaller than desired. Annealing may be used to increase grain size, however, because selenium vaporizes at a lower temperature than cadmium, and selenium can react or combine with other gases that may be present during an annealing process, some existing annealing techniques may produce an undesirable number of selenium vacancies (V_{Se}) in a crystal lattice of a resulting polycrystalline film. Improved layers and photovoltaic devices can be produced by controlling aspects of the deposition process, post-deposition treatment, and device fabrication.

CdSe based absorber layers can be used for an upper submodule of a tandem module. Provided herein are various embodiments and material choices for making a high-performance devices. The embodiments provided herein relate to aspects of high quality CdSe based solar cells including: material quality impact to performance, formation of p-n junctions and architecture for n-type CdSe absorbers. Modulation of polycrystalline grain quality in cadmium selenide can be achieved by controlling a combination of factors. These factors include deposition conditions and post-deposition treatment. The CdSe layer can be n-type. An absorber layer comprising n-type CdSe can form a p-n junction with a hole contact comprising a p-type layer having high bandgap and large workfunction.

When conditions are controlled according to described methods, properties of resulting polycrystalline films are improved. Example methods can be used to produce a cadmium selenide polycrystalline film having an average grain size of about 1.3 μm to 3.0 μm, incorporation of an oxygen dopant, increased uniformity of crystal grain size and orientation, reduced selenium vacancies (V_{Se}), and a shift in the proportion of grains having (103) lattice orientation relative to (002) lattice orientation. Devices incorporating the film can exhibit improved efficiency, average n-type charge carrier concentration in a range of about 1×10¹³ to 1×10¹⁷, average minority p-type charge carrier lifetimes greater than 1 nanosecond (ns), and decreased propensity for delamination.

According to the embodiments provided herein, a photovoltaic device can include an absorber layer and a hole contact. The absorber layer can include CdSe. The absorber layer can be n-type. The hole contact can form a p-n junction with the absorber layer.

According to the embodiments provided herein, a tandem photovoltaic device can include an upper submodule over a lower submodule. The upper submodule can include an absorber layer and a hole contact. The absorber layer of the upper submodule can include CdSe. The absorber layer can be n-type. The hole contact can form a p-n junction with the absorber layer.

According to the embodiments provided herein, a method for forming a photovoltaic device can include heating an absorber layer consisting essentially of CdSe in the presence of a halogen compound. A grain size of the absorber layer can grow and the halogen can diffuse into the absorber layer. The absorber layer can be heated, after the halogen is diffused, in air to reduce a quantity of the halogen from the absorber layer. The absorber layer can be heated, after the quantity of halogen is present or removed, in a Se environment to fill vacancies in the absorber layer.

According to the embodiments provided herein, a method for forming a photovoltaic device can include depositing a layer of CdSe onto a layer stack by vapor transport deposition, and treating the layer to modify its properties. Treating the layer can include contacting the CdSe layer with a halogen compound, and optionally an accelerant, and heating the CdSe layer on the layer stack in a controlled environment. The controlled environment can include selenium, oxygen, and nitrogen. The method can include forming the CdSe layer over and in contact with a buffer layer of the layer stack. The method can include forming a hole transport layer (HTL) over and in contact with the CdSe layer.

Embodiments of the present technology relate to tandem photovoltaic devices that include a first submodule and a second submodule; however, it should be recognized that such tandem photovoltaic devices can include additional submodules as well as additional arrangements of submodules. Submodules in a tandem photovoltaic device can be stacked and separated by the interlayer. Incident electromagnetic radiation, or light, enters the device through a front or top surface and enters the upper submodule. Light that is not absorbed by the upper submodule, can be transmitted to the back cell or lower submodule. Multi-junction solar cells can achieve higher total conversion efficiency than single junction cells by capturing a larger portion of the solar spectrum. These devices can be formed with materials having different band-gap properties responsive to different ranges of the spectrum. For a device where the primary light source is from above, light-incident upon the uppermost cell can have a large band gap to capture energetic short wavelengths, while a lower cell can have a smaller band gap to captures longer wavelengths and reflected photons.

Tandem photovoltaic devices can include bifacial devices, configured to receive incident radiation through both front and rear surfaces. Bifacial tandem devices can be configured to receive direct solar radiation on a top or front surface and receive radiation reflected from external surfaces, including visible and infrared light, on a back or rear surface.

The tandem photovoltaic device can generate electrical power by converting light into direct current electricity using semiconductor materials that exhibit the photovoltaic effect. The photovoltaic effect generates electrical power upon exposure to light as photons are absorbed within the semiconductor material to excite electrons to a higher energy state. These excited electrons can move within the material, resulting in an electrical current. Each submodule of a tandem device may comprise one or more semiconductor materials. Semiconductor materials suitable for use in photovoltaic devices can include, for example, type II-VI materials—including cadmium selenide and cadmium telluride alloys; type III-V materials—including GaAs and InGaN; type I-III-VI materials—including CIGS and CIS materials; as well as silicon—including amorphous silicon a-Si; and perovskites—including organic-inorganic ABX₃ materials.

The term “light” can refer to various wavelengths of the electromagnetic spectrum such as, but not limited to, wavelengths in the ultraviolet (UV), infrared (IR), and visible portions of the electromagnetic spectrum. “Sunlight.” as used herein, refers to light emitted by the sun.

The term “layer” can refer to a thickness of material provided upon a surface. The layer can cover all or a portion of the surface. A layer may include sublayers and can have compositional gradients within a layer. A layer can include one or more functional layers of material.

Unless otherwise specified, values for material properties correspond to conditions at normal temperature and pressure, 20 degrees C. and 1 atmosphere pressure.

Unless specified otherwise, values for provided ranges are inclusive of endpoints and include all distinct values and further divided ranges within the entire range.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer, or section. Terms such as “first,” “second,” and other numerical terms when used herein do not imply a sequence or order unless clearly indicated by the context. Thus, a first element, component, region, layer, or section discussed below could be termed a second element, component, region, layer, or section without departing from the teachings of the example embodiments.

Regarding methods disclosed, the order of the steps presented is exemplary in nature, and thus, the order of the steps can be different in various embodiments, including where certain steps can be simultaneously performed, unless expressly stated otherwise.

When an element or layer is referred to as being “on.” “engaged to,” “connected to,” or “coupled to” another element or layer, it may be directly on, engaged, connected, or coupled to the other element or layer, or intervening elements or layers may be present. In contrast, when an element is referred to as being “directly on.” “directly engaged to.” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items. “A” and “an” as used herein indicate “at least one” of the item is present; a plurality of such items may be present, when possible.

Spatially relative terms, such as “inner,” “outer,” “beneath,” “below,” “lower,” “above,” “upper,” and the like, may be used herein for case of description to describe one element or feature's relationship to another element(s) or feature(s) as illustrated in the figures. Spatially relative terms may be intended to encompass different orientations of the device during manufacturing, or in use or operation, in addition to the orientation depicted in the figures. For example, if the device in the figures is turned over, elements described as “below” or “beneath” other elements or features would then be oriented “above” the other elements or features. The device may be otherwise oriented (rotated 90 degrees or at other orientations) and the spatially relative descriptors used herein interpreted accordingly.

The term “absorber layer” as used herein refers to a semiconducting layer wherein the absorption of electromagnetic radiation causes electrons in the absorber layer to be excited from a lower energy “ground state” or “valence band” in which they are bound to specific atoms in the solid, to a higher “excited state,” or “conduction band” in which they can move about within the solid.

As used herein, “n-type layer” refers to a semiconductor layer having electron donors providing an excess of electrons in conduction band as majority carriers; while a “p-type layer” refers to a semiconductor layer having electron acceptors causing a deficit of electrons in the valence band (also referred to as an excess of “holes”) that serve as the majority carriers. In each case the excess carriers (electrons or holes) may be provided by chemically doping the semiconductor with suitable dopants or may be generated by intrinsic properties and defects present in the material. For junction partners in PV device, n-type and p-type layers or materials are interfaced together, to form a p-n junction.

Semiconductors doped to be p-type or n-type are sometimes further characterized based on the density of respective majority charge carriers. Although the boundaries are not rigid, a material is generally considered p-type if electron acceptor carriers (i.e. “holes”) are present in the range of about 1×10¹¹ cm⁻³ to about 1×10¹⁷ cm⁻³, and p+type if acceptor carrier density is greater than about 1×10¹⁷ cm⁻³. Similarly, a material is considered n-type if electron donor carriers are present in the range of about 1×10¹¹ cm⁻³ to about 1×10¹⁷ cm⁻³, and n+type if donor carrier density is greater than about 1×10¹⁷ cm⁻³. The boundaries are not rigid and may overlap because a layer may be p+ relative to a layer that is p-type (or n+ relative to a layer that is n-type) if the carrier concentration is at least 2 orders of magnitude (i.e. 100-fold) higher, regardless of the absolute carrier density. Additionally, some consider charge densities of greater than about 1×10¹⁹ cm⁻³ to be “++” type; and thus a layer of either n-type or p-type can be “++” relative to a layer of the same type that is itself “+” relative to yet a third layer, if the ++ layer has a same-type carrier density more than 100 fold that of the + layer.

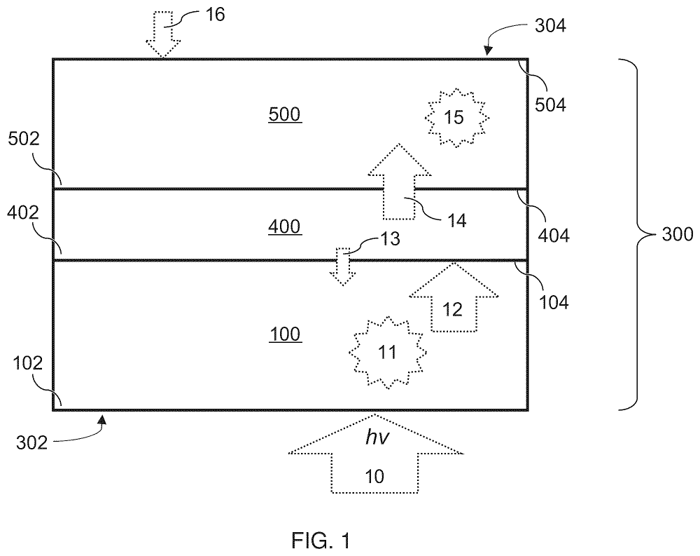

Turning now to the figures, with reference to FIGS. 1 & 5, an embodiment of a tandem photovoltaic device 300 is shown. The tandem photovoltaic device 300 can be configured to receive light and transform light into electrical energy, as photons are absorbed from the light and transformed into electrical current via the photovoltaic effect. For sake of discussion and clarity, the tandem photovoltaic device 300 can define a front side 302 configured to face a primary light source such as, for example, the sun. Additionally, the tandem photovoltaic device 300 can also define a back side 304 offset from the front side 302 such as, for example, by a plurality of functional layers of material.

The tandem photovoltaic device 300 can have an upper submodule 100, a lower submodule 500, and an interlayer 400 therebetween. The upper submodule 100 can also be termed a top cell, front cell, or first submodule. The lower submodule 500 can also be termed a bottom cell, back cell, or second submodule. The interlayer 400, can also be termed an interlayer stack, a dielectric stack, or a transparent coupling layer. Each of the upper submodule 100, the lower submodule 500, and the interlayer 400 can comprise a plurality of layers. Each of the upper and lower submodules 100, 500 of the tandem photovoltaic device 300 can include one or more absorber layers for converting light into charge carriers, and conductive layers for collecting the charge carriers.

The upper submodule 100 can have a first surface 102 substantially facing the front side 302 of the tandem photovoltaic device 300 and a second surface 104 substantially facing the back side 304 of the photovoltaic device 300. The interlayer 400 can have a first surface 402 substantially facing the front side 302 of the photovoltaic device 300 and a second surface 404 substantially facing the back side 304 of the photovoltaic device 300. The lower submodule 500 can have a first surface 502 substantially facing the front side 302 of the photovoltaic device 300 and a second surface 504 substantially facing the back side 304 of the photovoltaic device 300.

As depicted in FIG. 1, incident light (hv) 10 can enter the front side 302 of the tandem photovoltaic device 300 through the upper submodule 100 and a first portion 11 of light energy can be absorbed by the upper submodule 100 and a remaining portion 12 of light energy can pass through the upper submodule 100 to the interlayer 400. At the interlayer 400, reflected light 13 can be directed back toward the absorptive region of the upper submodule 100 and transmitted light 14 can pass to the lower submodule 500. Optionally, in a bifacial tandem device, back side light energy 16 can enter the back side 304 of the tandem photovoltaic device 300 toward the lower submodule 500. In many implementations, back side light energy 16 can include externally reflected visible light and near infrared light. The upper submodule can absorb the first portion 11 of light energy, which can include an absorbed combination of the incident light 10 and the reflected light 13. The lower submodule can absorb a second portion 15 of light energy comprising the transmitted light 14 and, optionally, the back side light energy 16.

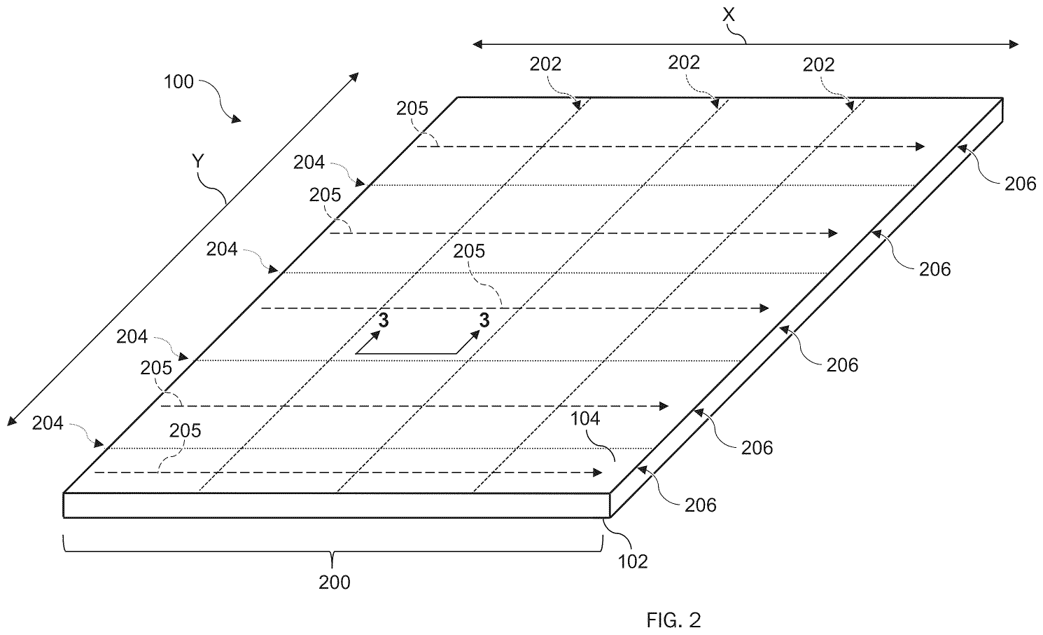

Referring now to FIG. 2, an example embodiment of the upper submodule 100 of the tandem photovoltaic device 300 is shown. The upper submodule 100 can include a plurality of layers disposed between the front side 102 and the back side 104. In some embodiments, the layers of the upper submodule 100 can be divided into an array of photovoltaic cells 200. For example, the upper submodule 100 can be scribed according to a plurality of serial scribes 202 and a plurality of parallel scribes 204. The serial scribes 202 can extend along a length Y of the upper submodule 100 and demarcate the photovoltaic cells 200 along the length Y of the upper submodule 100. Neighboring cells of the photovoltaic cells 200 can be serially connected along a width X of the upper submodule 100. In other words, a monolithic interconnect of the neighboring cells 200 can be formed; e.g., adjacent to the serial scribe 202. The parallel scribes 204 can extend along the width X of the upper submodule 100 and demarcate the photovoltaic cells 200 along the width X of the upper submodule 100. Under operation, current 205 can predominantly flow along the width X through the photovoltaic cells 200 serially connected by the serial scribes 202. Under operation, parallel scribes 204 can limit the ability of current 205 to flow along the length Y. Parallel scribes 204 are optional and can be configured to separate the photovoltaic cells 200 that are connected serially into groups 206 arranged along length Y.

With continuing reference to FIG. 2, the parallel scribes 204 can electrically isolate the groups 206 of photovoltaic cells 200 that are serially connected. In some embodiments, the groups 206 of the photovoltaic cells 200 can be connected in parallel such as, for example, via electrical bussing. Optionally, the number of parallel scribes 204 can be configured to limit a maximum current generated by each group 206 of the photovoltaic cells 200. In some embodiments, the maximum current generated by each group 206 can be less than or equal to about 200 milliamps (mA) such as, for example, less than or equal to about 100 mA in one embodiment, less than or equal to about 75 mA in another embodiment, or less than or equal to about 50 mA in a further embodiment.

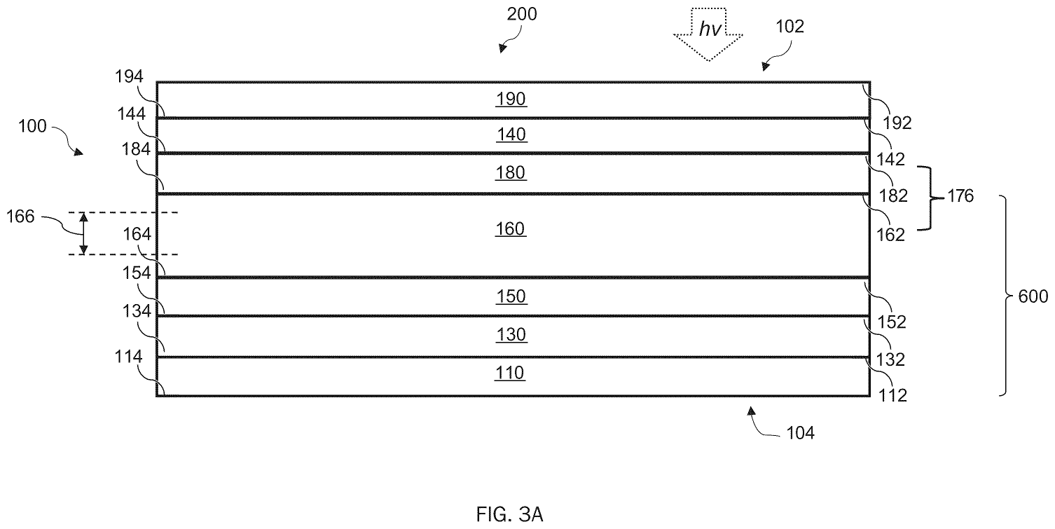

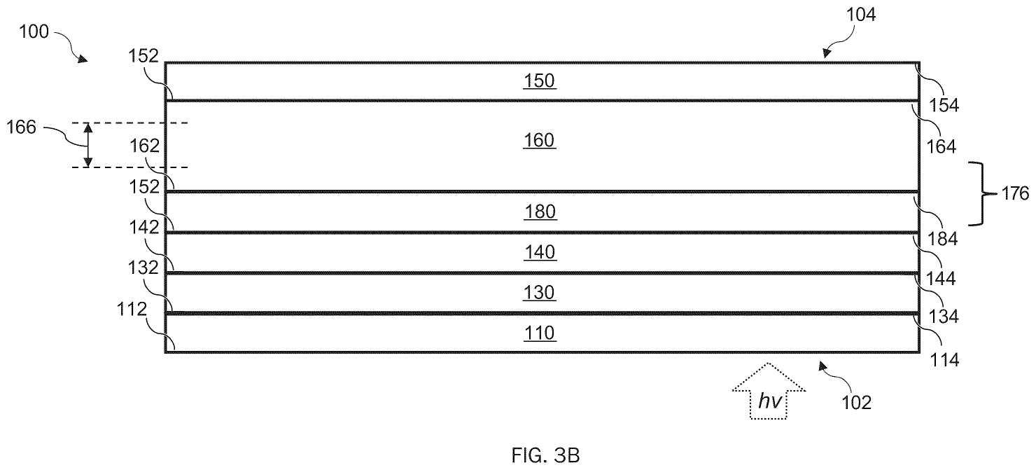

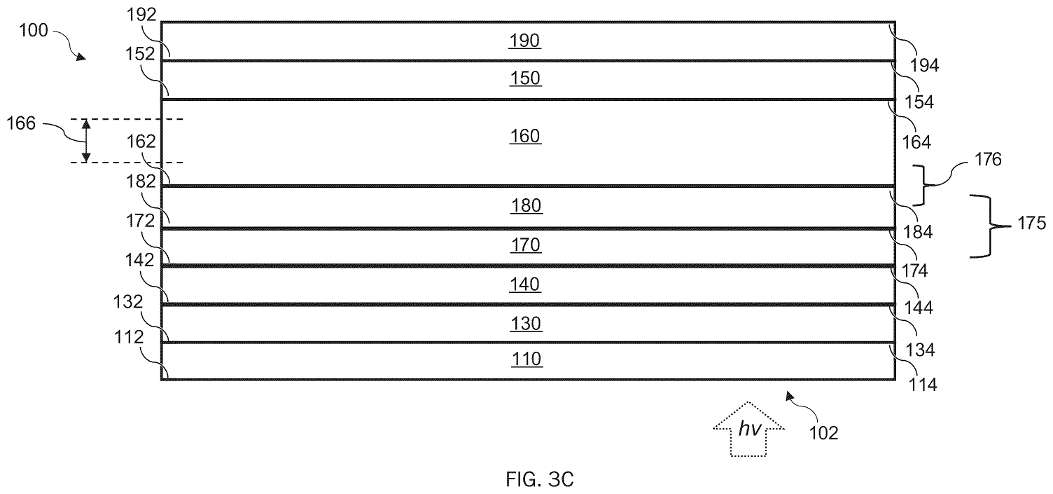

Turning to FIG. 3A-3C, the layers of the upper submodule 100 can include a thin film stack comprising a plurality of layers. The layers can be provided over a substrate 110. The substrate 110 can be configured to facilitate the transmission of light into the upper submodule 100. The substrate 110 can be disposed at the front side 102 of the upper submodule 100. The substrate 110 can have a first surface 112 substantially facing the front side 102 of the upper submodule 100 and a second surface 114 substantially facing the back side 104 of the upper submodule 100. One or more layers of material can be disposed between the first surface 112 and the second surface 114 of the substrate 110.

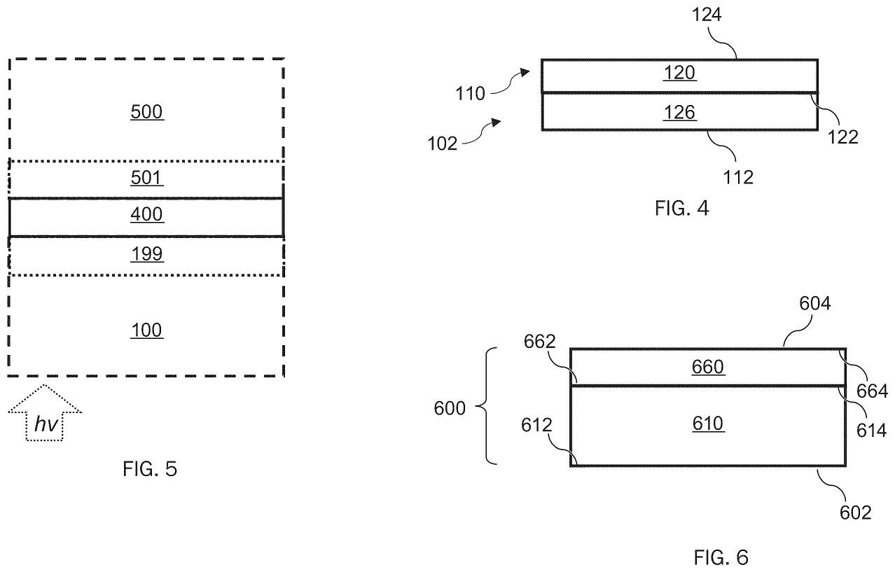

Referring now to FIG. 4, the substrate 110 can include a transparent layer 120 having a first surface 122 substantially facing the front side 102 of the upper submodule 100 and a second surface 124 substantially facing the back side 104 of the upper submodule 100. In some embodiments, the second surface 124 of the transparent layer 120 can form the second surface 114 of the substrate 110.

The transparent layer 120 can comprise a substantially transparent material such as, for example, glass. Suitable glass can include soda-lime glass, or any glass with reduced iron content. The transparent layer 120 can have any suitable transmittance range, including about 250 nm to about 1,300 nm, in some embodiments. The transparent layer 120 can also have a transmittance percentage, including, for example, more than about 50% in one embodiment, more than about 60% in another embodiment, more than about 70% in yet another embodiment, more than about 80% in a further embodiment, or more than about 85% in a further embodiment. In one embodiment, the transparent layer 120 can be formed from a glass with about 90% transmittance, or more. Optionally, the substrate 110 can include a coating 126 applied to the first surface 122 of the transparent layer 120. The coating 126 can be configured to interact with light or to improve durability of the substrate 110 such as, but not limited to, an antireflective coating, an antifouling coating, or a combination thereof.

Referring again to FIG. 3A-3C, the upper submodule 100 can include a barrier layer 130 configured to mitigate diffusion of contaminants from the substrate 110, which could result in degradation or delamination of other layers of the photovoltaic stack. The barrier layer 130 can have a first surface 132 substantially facing the front side 102 of the upper submodule 100 and a second surface 134 substantially facing the back side 104 of the upper submodule 100. In some embodiments, the barrier layer 130 can be provided adjacent to the substrate 110. For example, the first surface 132 of the barrier layer 130 can be provided upon the second surface 114 of the substrate 110.

Generally, the barrier layer 130 can be substantially transparent, thermally stable, with a reduced number of pin holes, have sodium-blocking capability, and good adhesive properties. The barrier layer 130 can include one or more layers of material. Example materials can include, but are not limited to: tin oxide, silicon dioxide, aluminum-doped silicon oxide, silicon oxide, silicon nitride, or aluminum oxide. The barrier layer 130 can have a thickness bounded by the first surface 132 and the second surface 134. In an example, a barrier layer thickness can be greater than 5 nanometers (nm), equal to or greater than 10 nm, or equal to or greater than 15 nm. In an example, a barrier layer thickness can be less than or equal to 50 nm, less than 40 nm, or less than or equal to about 20 nm.

The upper submodule 100 can include an n-type contact layer 150. The n-type contact layer 150 may also be called a negative charge transport layer, an n-type contact, an e-selective contact, electron transport layer (ETL), or an electron-selective layer As a selective contact to the absorber, this layer helps channel electrons from the absorber to a highly conductive electron contact while minimizing holes that can recombine at that contact. Additionally this layer comprises a highly conductive region that allows electrons to be channeled without significant series resistance. The n-type contact layer 150 can have a first surface 152 substantially facing the front side 102 of the upper submodule 100 and a second surface 154 substantially facing the back side 104 of the upper submodule. The n-type contact layer 150 has a thickness defined by a distance between the first surface 152 and the second surface 154. In some embodiments, the thickness of the n-type contact layer 150 is greater than 2 nm, in a range of 10 nm to 180 nm, or between 15 nm and 80 nm in an example embodiment.

The n-type contact layer 150 can comprise an n++ or n+ material or a combination thereof. The n-type contact layer 150 can comprise a conductive oxide. In an example, the n-type contact layer 150 can comprise a material, including, but not limited to, tin dioxide, doped tin dioxide (e.g., F—SnO₂), indium tin oxide, or cadmium tin oxide (Cd₂SnO₄).

The upper submodule 100 includes an absorber layer 160 comprising a material configured to cooperate with an adjacent layer to form a p-n junction within the photovoltaic device. Accordingly, absorbed photons of light can free electron-hole pairs and generate carrier flow, which can yield electrical power. The absorber layer 160 can have a first surface 162 substantially facing the front side 102 of the upper submodule 100 and a second surface 164 substantially facing the back side 104 of the upper submodule. A thickness of the absorber layer 160 can be defined between the first surface 162 and the second surface 164. In an example device, the thickness of the absorber layer 160 can be between about 200 nm to about 10000 nm. In some examples, the absorber layer 160 thickness is equal to or greater than 400 nm, 500 nm, 600 nm, 700 nm, 800 nm, 900 nm, 1000 nm, 1100 nm, 1200 nm, 1300 nm, 1500 nm, 1600 nm, 1800 nm, 2000 nm, 2200 nm, or equal to or greater than 2400 nm. In some examples, the absorber layer 160 thickness is less than or equal to 10000 nm, 5000 nm, 4000 nm, 3500 nm, 3000 nm, 2800 nm, 2500 nm, 2000 nm, 1800 nm, 1600 nm, 1500 nm, 1300 nm, or less than or equal to 1200 nm. In one example, the absorber layer has a thickness in a range of 700 nm to 1500 nm; in another example, the absorber layer has a thickness in a range of 1200 nm to 2500 nm.

The absorber layer 160 can comprise a polycrystalline type II-VI thin film semiconductor where electrons are excited to generate the photovoltaic effect. The absorber layer 160 can comprise an n type material. The absorber layer can be n-type throughout its thickness. The absorber layer can include CdSe. The absorber layer can consist essentially of CdSe. The absorber layer can comprise cadmium, selenium, and one or more dopants. In some embodiments, the absorber layer 160 comprises a dopant selected from: oxygen, chlorine, rubidium, sulfur, bromine, fluorine, iodine, cesium, potassium, sodium, lithium, or combinations thereof.

In some embodiments, the absorber layer has compositional and structural properties to reduce charge carrier recombination rates, increase carrier diffusion length, and increase carrier lifetimes. These properties can include, for example, layer thickness, stoichiometry, dopant concentrations, vacancy concentrations, grain size, and polycrystalline structure and orientation. In some embodiments, average carrier diffusion length is greater than 10 nm, 20 nm, 50 nm, 70 nm, 100 nm, 200 nm, 700 nm, 800 nm, 1000 nm, 1200 nm, or in a range of 20 nm to 1500 nm. In some embodiments, average carrier lifetimes are equal to or greater than 1 ns, 2 ns, 5 ns, 10 ns, 15 ns, greater than 20 ns, or in a range of 1 ns to 100 ns.

In some embodiments, an atomic concentration of oxygen in a central region 166 of the absorber layer 160 can be greater than about 1×10¹⁶ cm⁻³, such as, for example, between about 1×10¹⁷ cm⁻³ and about 5×10²⁰ cm⁻³ in one embodiment, between about 3×10¹⁷ cm⁻³ and about 1×10¹⁹ cm⁻³ in another embodiment, or between about 5×10¹⁷ cm⁻³ and about 5×10¹⁸ cm⁻³ in a further embodiment. In some embodiments, the absorber layer includes oxygen at an average concentration in a range of 1×10¹⁷ cm⁻³ to 1×10¹⁹ cm⁻³ in a central region of the absorber layer. The central region 166 is the middle 50% of the absorber layer 160, which is offset by 25% of the thickness of the absorber layer 160 from each of the first surface 162 and the second surface 164 of the absorber layer 160. Alternatively or additionally, the concentration profile of oxygen can vary through the thickness of the absorber layer 160.

In some embodiments, an atomic concentration of chlorine in a central region 166 of the absorber layer 160 can be less than about 1×10²¹ cm⁻³, such as, for example, between about 1×10¹⁷ cm⁻³ and about 1×10²¹ cm⁻³ in one embodiment, between about 5×10¹⁷ cm⁻³ and about 1×10²⁰ cm⁻³ in another embodiment, or between about 5×10¹⁷ cm⁻³ and about 5×10¹⁹ cm⁻³ in a further embodiment.

The upper submodule 100 includes a hole contact 180. The hole contact 180 may also be called a positive charge transport layer, p-type contact, hole transport material, hole transport layer (HTL), h+ selective contact, or a hole-selective layer. The hole contact 180 provides electrical contact to the absorber layer 160. The hole contact 180 can have a first surface 182 substantially facing the front side 102 of the upper submodule 100 and a second surface 184 substantially facing the back side 104 of the upper submodule.

A thickness of the hole contact 180 can be defined between the first surface 182 and the second surface 184. In some embodiments, the thickness of the hole contact 180 can be between about 2 nm to about 200 nm, or, between about 2 nm to about 100 nm.

In some embodiments, the hole contact 180 is a polymer, a small molecule, or an inorganic compound. In some embodiments, the hole contact 180 comprises a metal oxide or a metal oxynitride. In some embodiments, the hole contact 180 comprises a transition metal oxide.

The hole contact 180 can comprise an organic hole transport material (HTM). In an example, the hole contact comprises at least one of: poly[bis(4-phenyl)(2,4,6-trimethylphenyl)amine (PTAA); perylene diimide (PDI); 4,4′-Bis(N-carbazolyl)-1,1′-biphenyl (CBP); Tris(4-carbazoyl-9-ylphenyl)amin (TCTA); 1,3,5-tris(carbazol-9-yl)benzene (TCP); poly(9,9-dioctylfluorene-alt-benzothiadiazole) (F8BT). In another example, the hole contact consists essentially of an organic HTM selected from: PTAA, PDI, CBP, TCTA, TCP, or F8BT.

The hole contact 180 can comprise an inorganic material having good valence band alignment and wide bandgap. In an example, the hole contact comprises at least one of: copper aluminum sulfide (CuAlS₂); copper aluminum selenide (CuAlSe₂); copper gallium oxide (CuGaO₂); magnesium germanium phosphide (GcMgP₂); boron phosphide (BP); gallium phosphide (GaP); zinc selenide (ZnSe); or tantalum oxynitride (TaOₓN₍₁₋ₓ₎).

In some embodiments, the hole contact 180 comprises a p-type transparent conductive oxide. In some embodiments, the p-type transparent conductive oxide comprises at least one of: nickel oxide (NiOₓ) or tin oxide (SnOₓ). In some embodiments, the p-type transparent conductive oxide is doped with at least one of: boron (B); magnesium (Mg); nitrogen (N); antimony (Sb); or combinations thereof.

In some embodiments, the hole contact 180 comprises a p-type alloy comprising at least one of: zinc (Zn), sulfur(S), selenium (Se); and tellurium (Te).

In some embodiments, the hole contact 180 comprises an inorganic compound selected from nickel oxide (NiOₓ), cuprous thiocyanate (CuSCN), copper iodide (CuI), or copper oxide (Cu₂O).

The hole contact 180 can combine materials with wide-bandgap and high work function. In some embodiments, the hole contact 180 comprises a buffer sublayer and a contact sublayer. In an example, a buffer sublayer can comprise molybdenum sulfide (MoSx) or tungsten sulfide (WSₓ). In an example, a contact sublayer can comprise niobium disulfide (NbS₂); vanadium sulfide (VₓSₓ); vanadium(II) sulfide(VS); tantalum sulfide (TaSₓ); tantalum(IV) sulfide (TaS₂); titanium sulfide (TiₓSₓ); titanium(IV) sulfide(TiS₂); or combinations thereof.

A composition for the hole contact 180, or for a sublayer of the hole contact 180, may be selected to provide a buffer and ohmic contact, or to have a good work function and band gap alignment to an adjacent layer. In some embodiments, a material of the hole contact 180 has a work function greater than 5 eV. The hole contact 180 can be p type or p+ type.

The hole contact 180 can form a p-n junction 176 with the absorber layer 160. The hole contact 180 can comprise a p type layer of the p-n junction 176, with the absorber layer comprising the n type layer of the p-n junction.

The upper submodule 100 can include a transparent conductive layer 140 configured to provide electrical contact to transport charge carriers generated by the first submodule 100. The transparent conductive layer 140 can have a first surface 142 substantially facing the front side 102 of the first submodule 100 and a second surface 144 substantially facing the back side 104 of the first submodule 100. The transparent conductive layer 140 can be positioned between the absorber layer and the front side 102 of the first submodule 100. In some embodiments, the p type hole contact 180 can be positioned between the n type absorber layer 160 and the transparent conductive layer 140. In some embodiments, for example in FIG. 3B, the transparent conductive layer 140 can be p+ type. In some embodiments, for example in FIGS. 3A and 3C, the transparent conductive layer 140 can be n type or n+ type.

The upper submodule 100 can optionally include a conducting layer 190. The conducting layer 190 can have a first surface 192 substantially facing the energy side 102 of the photovoltaic device and a second surface 194 substantially facing the back side 104 of the photovoltaic device.

In some embodiments, the upper submodule 100 can include a p+/n+ tunnel or recombination junction 175. In some embodiments, the hole contact 180 can form the p+ layer of the p+/n+ junction 175. In some embodiments, an n+layer 170 can form the n+ layer of the p+/n+ junction 175.

The functionality of the p+/n+ junction is two-fold. First, it forces a significant band-bending to cause a narrow depletion width across the p+/n+ junction that allows electrons and holes to tunnel or recombine. This process converts the holes that were the majority carriers in the p-contact into electrons that are the majority carriers in the n+ region. A second functionality of the electron collecting side of the p+/n+ junction is providing sufficiently low resistance for lateral transport of current, which can be accomplished through the n+ or n++ part of the TCO-like layer. These functions may be provided through a single layer, a layer with sublayers, or through use of a plurality of n-type layers, including one or more n+ and/or n++ layers.

In some embodiments, the n+ side of the n+/p+ junction 175 comprises a layer 170 of a metal oxide doped n+, and the layer of metal oxide comprises at least one of the following materials: tin oxide doped with fluorine (SnO₂:F); indium tin oxide (ITO); cadmium tin oxide (Cd₂SnO₄); tungsten(VI) oxide (WO₃); molybdenum(VI) oxide (MoO₃); chromium(VI) oxide (CrO₃); vanadium(V) oxide (V₂O₅); or combinations thereof. In some embodiments, the n+ side of the n+/p+ tunnel junction comprises at least one of the following materials: gallium phosphide (GaP); boron phosphide (BP); zinc selenide (ZnSe); or combinations thereof.

The photovoltaic device 100 can optionally include one or more interlayers, diffusion barrier layers, and/or one or more secondary buffer layers. The addition of one or more barrier layers or buffer layers may be used to inhibit diffusion of dopants or contaminants between layers. A buffer layer may be utilized to reduce the number of irregularities arising during the formation of a semiconductor. A buffer layer can be configured to provide an insulating layer between adjacent layers. The buffer layer may include material having higher resistivity than an adjacent layer, and may include, but is not limited to, intrinsic tin dioxide, zinc magnesium oxide (e.g., Zn₁₋ₓMgₓO), tin dioxide (SnO₂), silicon dioxide (SiO₂), aluminum oxide (Al₂O₃), aluminum nitride (AlN), zinc tin oxide, zinc oxide, tin silicon oxide, or combinations thereof. In some embodiments, the material of the buffer layer can be configured to substantially match the band gap of an adjacent semiconductor layer. The buffer layer may have a thickness, including, for example, more than about 10 nm in one embodiment, between about 10 nm and about 80 nm in another embodiment, or in a range of 15 nm to 60 nm in a further embodiment.

The submodule may further comprise additional layers and structural components, including but not limited to one or more of: a buffer layer, a barrier layer, an interfacial layer, a dielectric layer, a conductive layer, a support layer, an antireflective layer, scribing, encapsulation, bussing, and combinations thereof.

In a substrate structured device, the device can be formed over a substrate from back to front. In a superstrate structured device, the device can be formed over a substrate from front to back.

FIG. 3A shows an example submodule which may be prepared as a substrate structured device. In the example shown, In this example, the n type CdSe absorber layer 160 is between and adjacent to the p type hole contact layer 180 and n type contact 150.

FIG. 3B and 3C show example submodules which may be prepared as a superstrate structured device. The n type CdSe absorber layer 160 is between the p type hole contact layer 180 and the n type contact 150. In the example shown, an n+ or n++ layer is provided by the transparent conductive layer 140.

An example submodule is illustrated in FIG. 3C. In this example, the p type hole contact layer 180 is between the n type CdSe absorber layer 160 and the transparent conductive layer 140. This configuration can be facilitated by use of a n+/p+ junction 175. In some embodiments, the hole contact also functions as the p+ layer of the p+/n+ junction. Alternately, in some embodiments, an additional p+ layer is between the hole contact 180 and the absorber layer 160. Use of a TCO of the n++ variety may be selected as a practical choice as there are more compositional options for good transparent conducting oxides that are n-type, rather than p-type. Thus, for an n-type photovoltaic absorber to be used in a superstrate configuration, it can be advantageous to use a n+/p+ junction to convert the carrier type for making a p-n junction on the light entry, front side of the absorber. In a device provided with a good p++ layer comprising one or more materials, the structure can be simplified to a submodule architecture, from front to back, of: p++/p+/HTL/CdSe-n/ETL/n+/n++.

FIG. 6 shows a layer stack of a partly formed device. An absorber stack 600 comprises a substrate stack 610 and a semiconductor film 660. The absorber stack 600 can have a first surface 602 and a second or exposed surface 604. The substrate stack 610 comprises a substrate layer and a plurality of layers formed on the substrate layer. The semiconductor film 660 comprises as-deposited absorber material. The semiconductor film 660 is provided as a layer at a surface of the absorber stack 600 and the as-deposited absorber precursor material can be treated to form the absorber layer. The semiconductor film 660 can have a first surface 662 or stack-contacting surface, and can have a second surface or exposed surface 664. Treatment of the as-deposited semiconducting layer 660 can be applied to the exposed surface 664 of the film which corresponds to the exposed surface 604 of the absorber stack 600.

For embodiments formed in a superstrate configuration, the absorber stack 600 can have a first surface 602 substantially facing the front side 102 of the first submodule 100 and a second surface 604 substantially facing the back side 104 of the first submodule 100. The substrate stack 610 can have a first surface 612 substantially facing the front side 102 of the first submodule 100 and a second surface or exposed surface 614 substantially facing the back side 104 of the first submodule 100. The semiconductor film 660 comprising CdSe can be deposited over and adjacent the substrate stack with a first surface 662 in direct contact with the second surface 614 of the substrate stack, to form the absorber stack 600.

Photovoltaic devices may contain several material layers deposited sequentially over a substrate. Steps for manufacturing a photovoltaic device may include sequentially disposing functional layers or layer precursors in a “stack” of layers through one or more deposition processes, including, but not limited to, spin coating, spray coating, slot coating, blade coating, dip coating, sputtering, evaporation, molecular beam deposition, pyrolysis, closed space sublimation (CSS), pulse laser deposition (PLD), chemical vapor deposition (CVD), electrochemical deposition (ECD), atomic layer deposition (ALD), or vapor transport deposition (VTD). The as-deposited layer or layer stack may be processed to modify characteristics using one or more methods, for example, by annealing, passivating, heating, vapor contact, or chemical treatment. Manufacturing of photovoltaic devices can further include the selective removal of portions of certain layers of the stack of layers, such as by scribing, to divide the photovoltaic device into a plurality of photovoltaic cells.

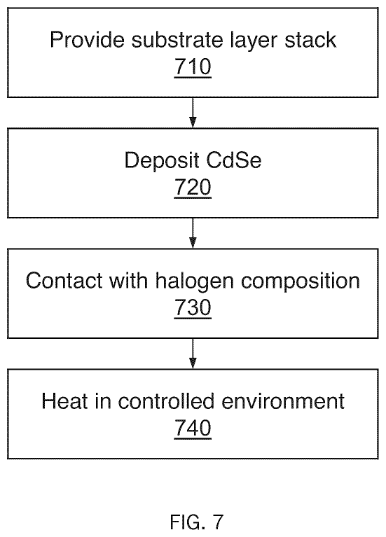

An example method is illustrated in FIG. 7. The method includes providing a substrate layer stack 710; depositing semiconductor film 720 to form an absorber stack; contacting the film with a halogen composition 730; and heating the absorber layer stack in a controlled environment 740.

The step of providing a substrate layer stack 710 can include preparing an exposed surface 614 of the substrate stack 610. In some embodiments the exposed surface 614 can be substantially smooth. In an example method for preparing a submodule in substrate orientation, a substrate layer stack 610 has an n-type top layer which may comprise a buffer material and an electron transport layer with a smooth top surface 614. In an example method for preparing a submodule in superstrate orientation, a substrate layer stack 610 can include a p-type hole transfer material. Optionally, the p-type hole transfer material can also be the p+ layer of a p+/n+ junction, over which the semiconductor film for forming the absorber layer is deposited.

The step of depositing semiconductor film 720 can include depositing cadmium selenide by vapor transport deposition (VTD). Use of VTD has been found to produce a better quality film as compared with other physical deposition methods. Control of the deposition temperature can also modulate qualities of the resulting film. In an example, the layer is deposited at a temperature of about 520 C, in a range of 480-560 C, or in a range of 500-540 C, using N₂ or N2 with fractional oxygen percentage as a carrier gas.

The step of contacting the film with a halogen composition 730 can include contacting the film with an alkali metal halide. The step of contacting the film with a halogen composition 730 can include contacting the film with an alkali metal chloride. The step may further include contacting the film with an accelerant. The contacting step may include providing the composition as a liquid, gel, or vapor. In some embodiments, the halogen compound comprises at least one of: CdCl6₂, NH₄Cl, CdBr₂, CdI₂, MgCl₂, or Ba(ClO₃)₂. In some embodiments, the accelerant comprises at least one of: Li, Na, K, Rb, or Cs. In an example, the contacting step may include contacting the film with cadmium chloride and rubidium chloride.

The step of heating the absorber layer stack in a controlled environment 740 can include providing an oxygenated environment. In some embodiments, the environment comprises Se. The step of heating the absorber layer stack in a controlled environment 740 can occur after or concurrent with the step of contacting the absorber stack with a halogen composition. The halogen composition may include cadmium chloride or other chloride compounds. The step of heating the absorber layer stack in a controlled environment 740 can also be referred to as a chloride heat treatment (CHT) or annealing step. The heating, after or with application of the halogen composition, and optionally the accelerant, in the presence of oxygen, and optionally selenium, can promote grain growth and diffusion of chloride and oxygen to the grain boundaries and into the bulk or central region of the absorber, and can reduce selenium vacancies in the film. Use of selenium in the controlled environment further reduces selenium vacancies.

In some embodiments, the environment comprises O₂ at an amount equal to or greater than 2%, 5%, 10%, 12%, 15%, 18%, or in a range up to 25%, or in a range up to 20%. In some embodiments, the environment comprises Se at an amount equal to or greater than 0.001%, 0.01%, 0.05%, 0.1%, 0.5%, 1.0%, in a range up to 5.0%, or in a range up to 2.5%, or in a range up to 2.0%. In some embodiments, the controlled environment comprises selenium vapor at a partial pressure in a range of 0.01 Torr to 60 Torr, or in a range of 0.1 Torr to 30 Torr. In some embodiments, the controlled environment has a temperature equal to or greater than 300 C, 320 C, 340 C, 350 C, 360 C, 370 C, 380 C, 390 C, or 400 C. In some embodiments, the controlled environment has a temperature less than or equal to 520 C, 500 C, 490 C, 480 C, 470 C, 460 C, or 450 C. In some embodiments, the controlled environment has a temperature in a range of 380 C to 500 C. In some embodiments, the controlled environment has a temperature in a range of 380 C to 475 C. In some embodiments, the controlled environment has a temperature in a range of 400 C to 440 C. In some embodiments, the controlled environment has a pressure equal to or less than about 760 Torr (1 atm). In some embodiments, the controlled environment has a pressure in a range of 250 Torr to about 760 Torr. In some embodiments, the environment has a pressure in a range of 250 Torr to 500 Torr. In some embodiments, the environment has a pressure in a range of 1.0 Torr to 500 Torr. In some embodiments, the environment has a pressure in a range of 50 Torr to 500 Torr with a partial pressure of oxygen in a range of 1.0 Torr to 125 Torr and a partial pressure of selenium in a range of 0.1 Torr to 30 Torr. In some embodiments, the step of heating the absorber layer stack in a controlled environment is performed for a duration of at least 20 minutes, at least 40 minutes, at least 60 minutes, at least 90 minutes, at least 120 minutes, at least 180 minutes. In some embodiments, the step of heating the absorber layer stack in a controlled environment is performed for a duration of less than 24 hours, less than 18 hours, less than 12 hours, less than 10 hours, less than 8 hours, less than 6 hours, less than 5 hours, less than 4 hours, or equal to or less than 3 hours. In some embodiments, the step of heating the absorber layer stack in a controlled environment is performed for a duration of 1-6 hours. In some embodiments, the step of heating the absorber layer stack in a controlled environment is performed for a duration of 1-3 hours.

Example absorber layers were prepared and treated, using selected deposition methods and differing post-deposition treatments, and the resulting absorber layers were characterized.

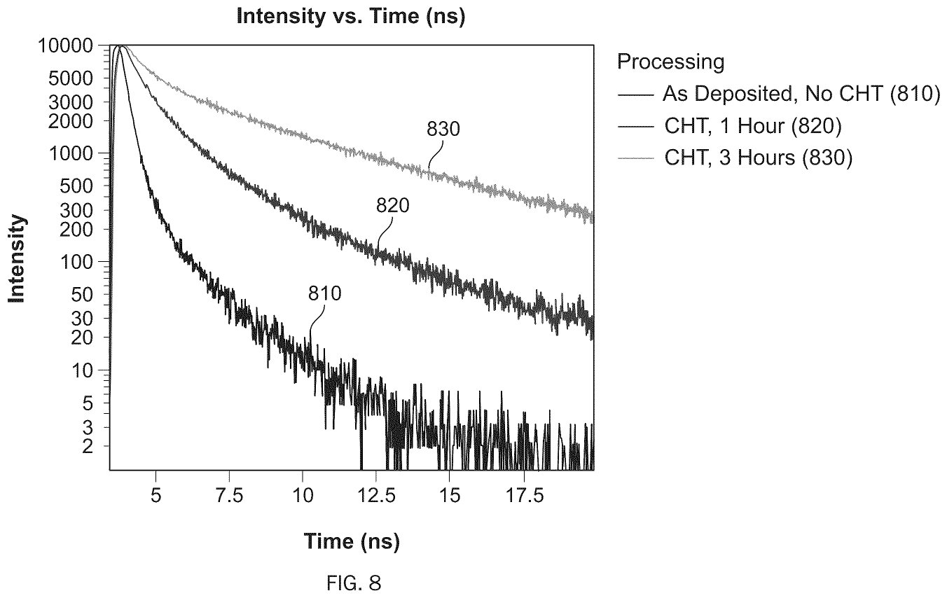

FIG. 8 shows transient curves of time-resolved photoluminescence intensity (TRPL) for as deposited and post-CHT CdSe films. Slower TRPL transient decay indicates improved minority carrier lifetime. Line 810 shows results for the as-deposited film without treatment, line 820 shows results after 1 hour of treatment, and 830 shows results after 3 hours of treatment. The as-deposited samples have poor lifetime. The CHT treatment process improves lifetime, with longer treatment times providing further increase. Average Lifetimes: As Deposited=0.04 ns (40 ps); 1 Hour=1 ns; 2 Hour=2 ns. Grain size also increases with CHT time.

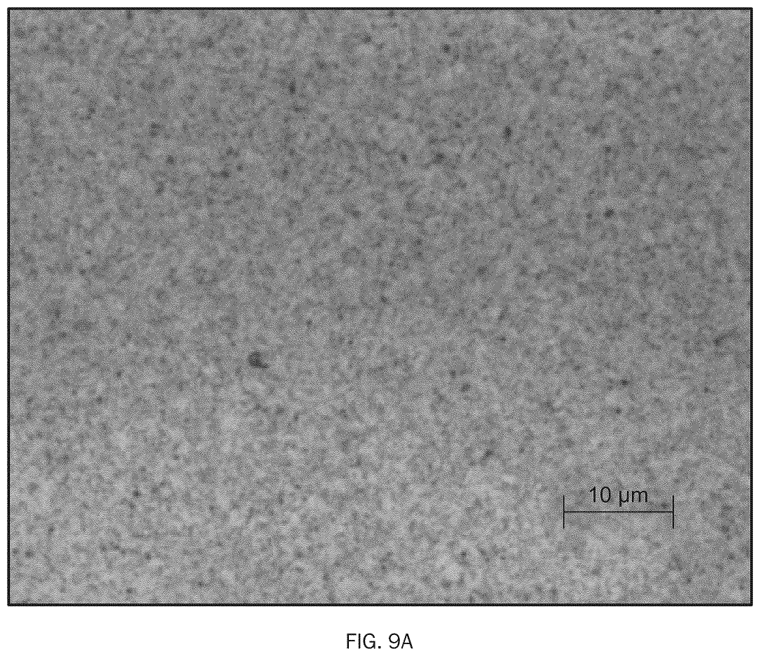

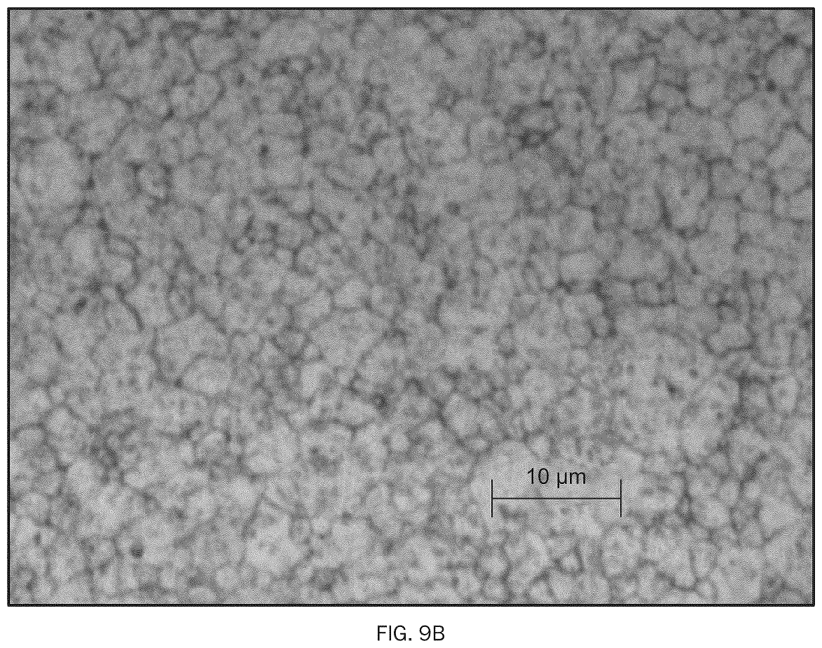

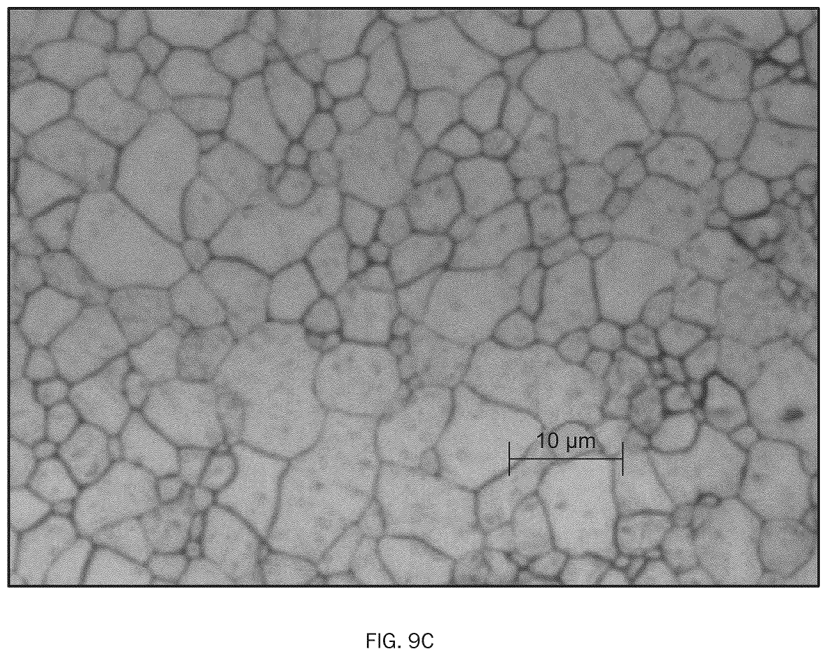

FIG. 9A, FIG. 9B, and FIG. 9C show optical microscope images at 100× magnification and show grain growth with increased CHT time. In some embodiments, the absorber layer is a polycrystalline film having a thickness in a range of 0.25 μm to 2.0 μm and an average grain size in a range of 1.3 μm to 3.0 μm. In some embodiments, an average grain size is equal to or greater than the absorber layer thickness.

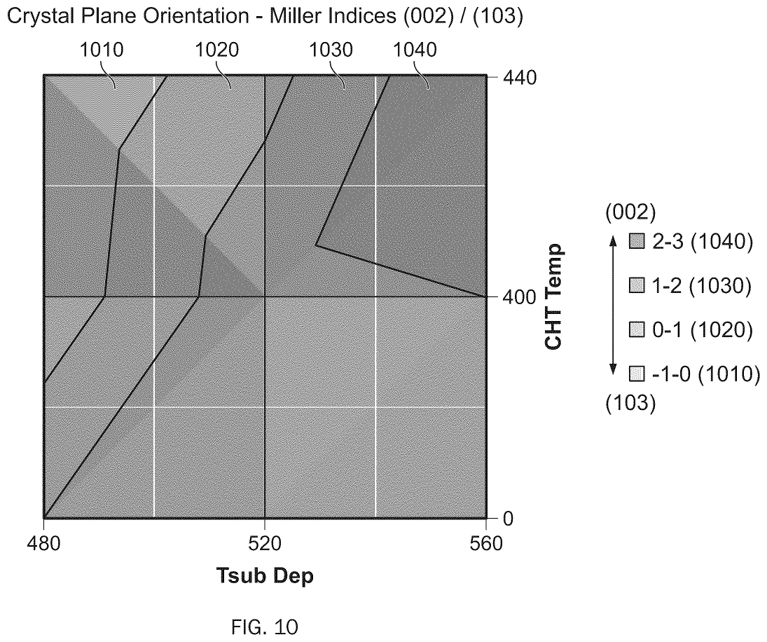

FIG. 10 shows post-CHT orientation contours with (hkl) Miller indices which indicate the orientation of a crystal plane. FIG. 10 shows the log of the ratio of (002) to (103) orientation. For example, the contour 1040 labeled 2-3 indicates that fraction, by area, of grains having (002) orientation is 100 to 1000 times (103) grains. The chart show contours 1040, 1030, 1020, 1010, showing a shift in the fraction, by area, of grains having (002) orientation relative to (103) grains. The data correspond to samples with deposition at 480 C, 520 C, or 460 C, and no CHT treatment, or treatment at 400 C or 440 C. Films, particularly those deposited at 520 C, start out as (002) and become increasingly (103) with CHT temperature and time. Samples deposited at 560 C, illustrated on the right side, are predominantly (002). Without wishing to be bound by theory, it has been found that films having a higher percentage of (103) orientation can also have improved optoelectronic properties. During growth, films nucleate easier as (002), at low temperature deposition, films are more random with respect to orientation (002) (103). During recrystallization, orientation shifts towards (103) to reduce surface energy.

In an example, the film has an as-deposited first crystal structure, with a first dominant crystal orientation, and a first average grain size. After treatment, the film has a treated second crystal structure with a second dominant crystal orientation, and a second average grain size. In some embodiments, the absorber layer is a polycrystalline film wherein a ratio of grains having (103) orientation relative to (002) orientation is equal to or greater than 1:1.

Concentration of dopants and constituent elements of an absorber layer can be measured by secondary-ion mass spectrometry (SIMs). FIG. 11 shows examples of comparative absorber layers characterized by Time-of-Flight-Secondary Ion Mass Spectrometry (ToF-SIMS).

As shown in FIG. 11, post-deposition treatments can produce semiconductor films with modified oxygen levels in a bulk region of the layer. Post-deposition treatment modulates both total oxygen and a ratio of O₂ to Se and O⁻ to Se by depth. The greater difference in O⁻, as compared with O₂, detected in the absorber indicates the degree to which the oxygen is incorporated into the film.

FIG. 11 shows counts of O⁻ and O₂ normalized to Se⁻ by depth for comparative absorber layer samples as measured by time of flight secondary ion mass spectroscopy (TOF-SIMS). The levels of oxygen in the bulk region or central portion of the thickness of the absorber can best illustrate changes due to processing, while oxygen levels near an exposed surface (depth=0) may be influenced by incidental air exposure. The four lines show results for an as-deposited layer 1110, a layer 1120 heat treated by cadmium chloride in a nitrogen environment, a layer 1130 heat treated with cadmium chloride in an air environment 1130, and a layer 1140 heat treated with cadmium chloride and subsequently subjected to a vacuum annealing step. The chart shows that a heat treatment, to promote grain growth, results in reduced oxygen content, and this can be ameliorated by inclusion of oxygen in a post-deposition treatment.

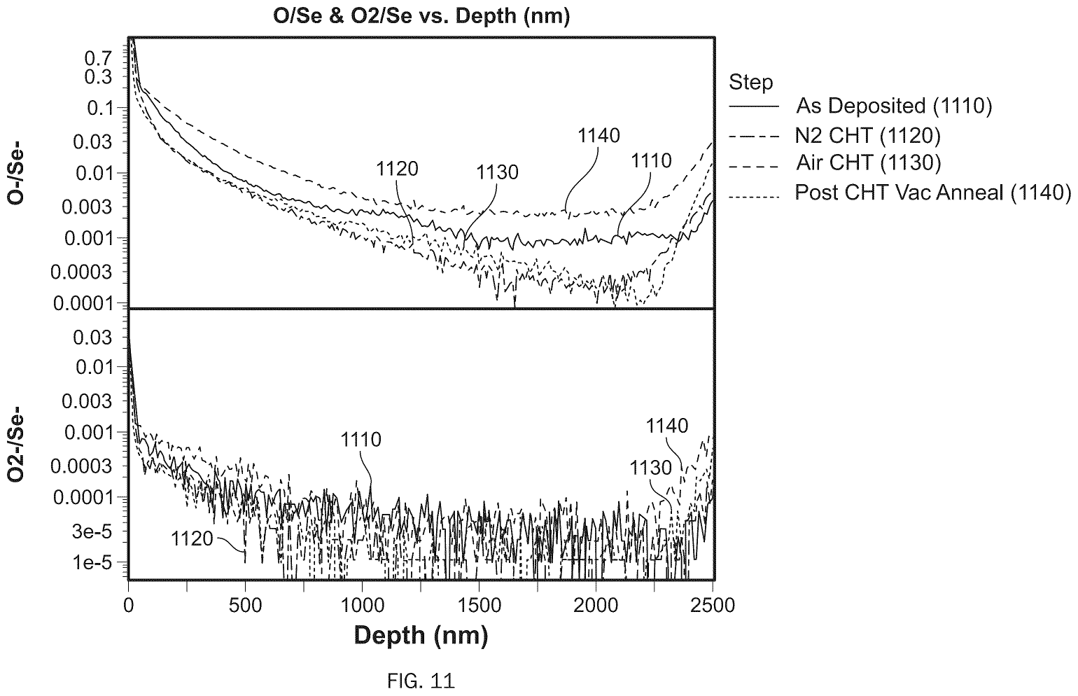

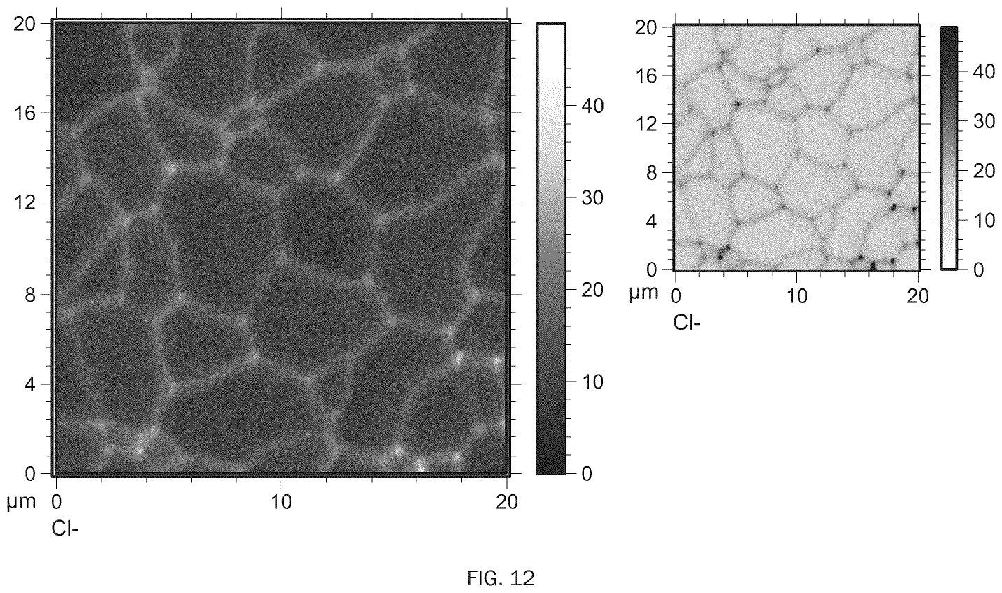

FIG. 12 shows Cl in grain boundaries for a CdSe layer after a post-deposition cadmium chloride heat treatment in an environment comprising oxygen in a range of 5% to 20%. The left panel shows the image as captured and the right panel shows the same image with color inversion and converted to grayscale.

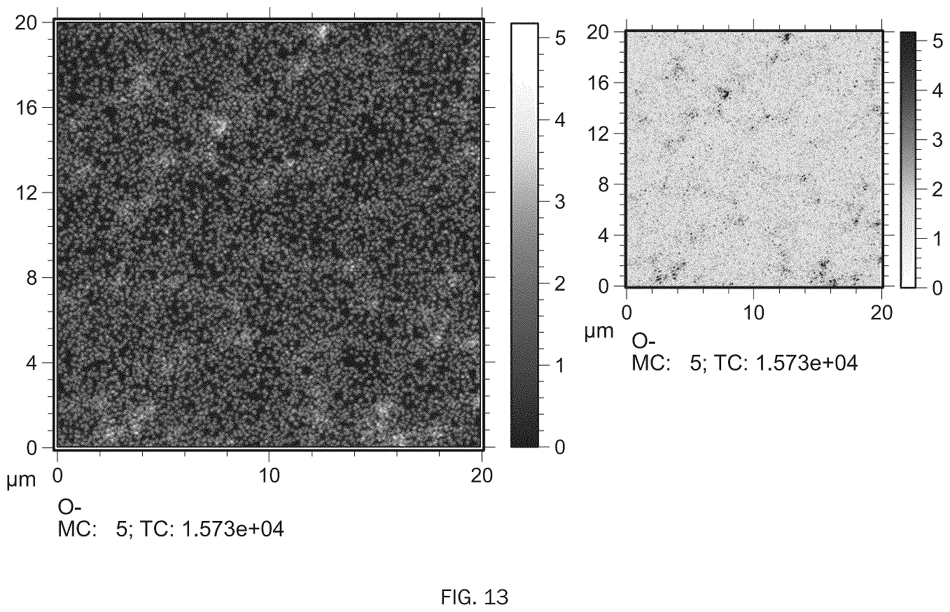

FIG. 13 shows oxygen in grain boundaries. The left panel shows the image as-captured, and the right panel shows the same image with color inversion and converted to grayscale. FIGS. 12 and 13 show the same sample area at the same scale. FIGS. 12 and 13 show the presence of both chlorine and oxygen in the film after CHT and show a higher concentration of both along grain boundaries.

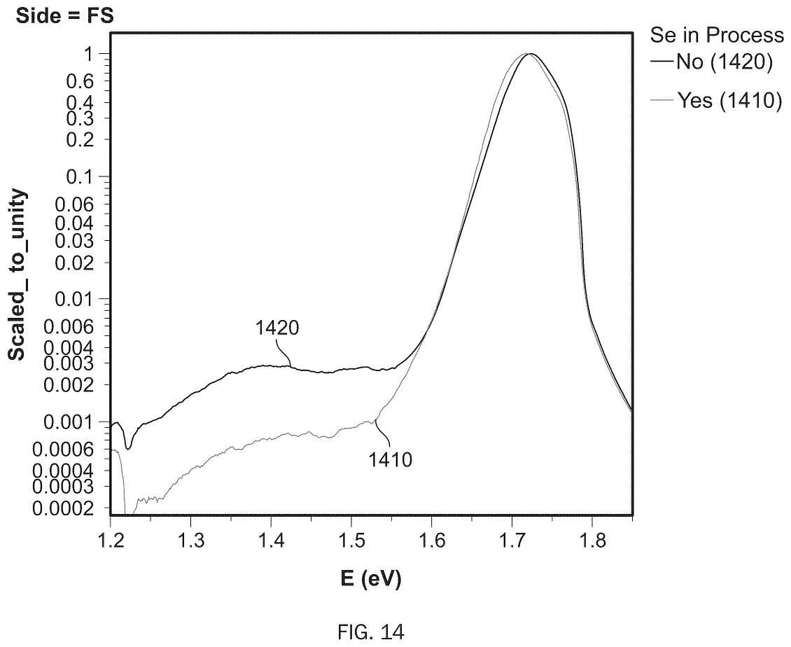

FIG. 14 shows measurements of CdSe semiconductor films produced with a halogen treatment and selenium vapor treatment or with a halogen treatment but without selenium vapor treatment. Data line 1410 shows results with Se treatment and data line 1420 shows results without Se treatment. The data indicate that addition of Se vapor treatment reduces sub bandgap intensity and improves optoelectronic properties.

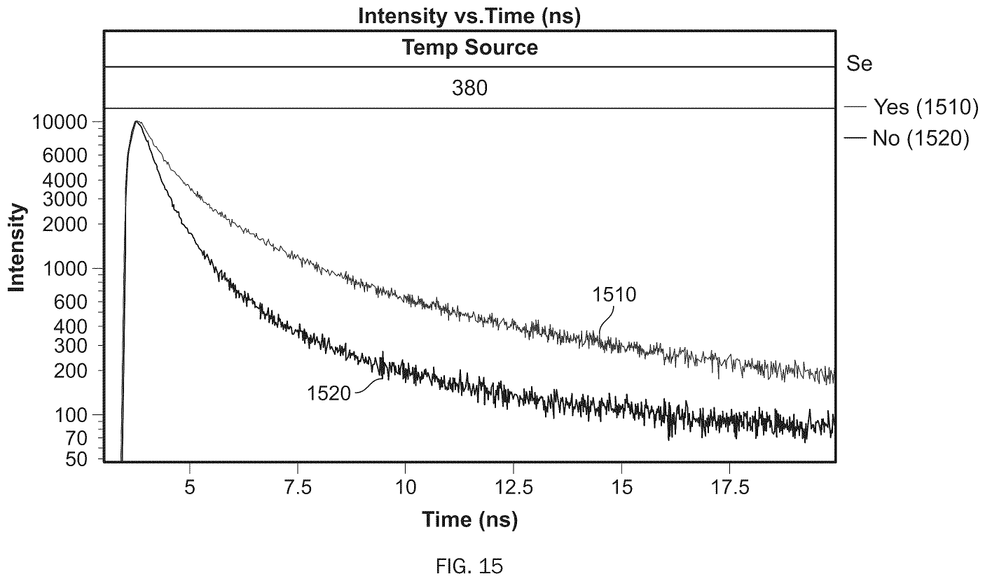

FIG. 15 shows transient curves of time-resolved photoluminescence intensity (TRPL) for CdSe layers produced with and without post-deposition Se treatment. Data corresponding to treatment with Se is shown by line 1510. Data corresponding to a control without Se treatment with is shown by line 1520. As shown, treatment with Se improves TRPL, indicating improved minority carrier lifetime.

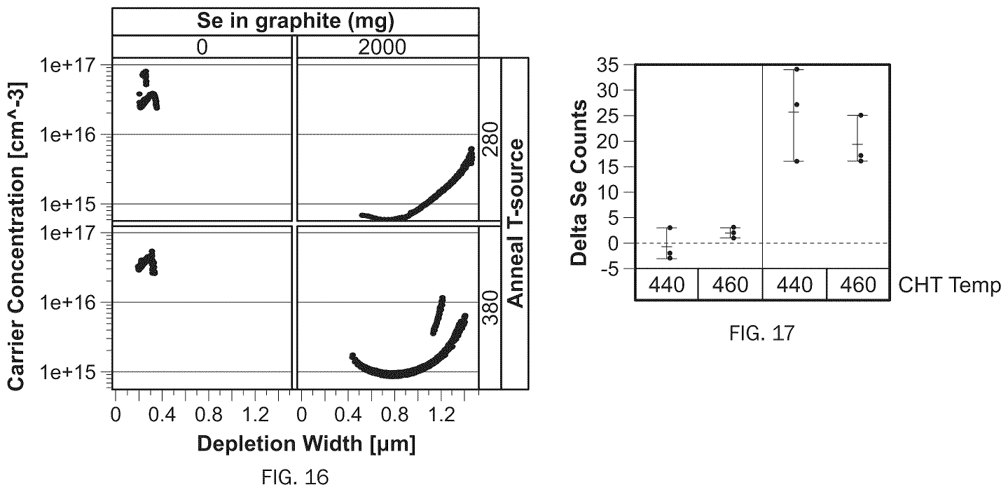

FIG. 16 shows capacitance-voltage (CV) measurements plotting charge carrier concentration per cubic cm, by depth, for CdSe absorbers after heat treatment. The data sets on the right show results after treatment in an environment including Se, and those on the left show treatment without Se. The data sets on the top show results after heat treatment at about 280 C. and the data sets on the bottom show results after heat treatment at about 380 C. Se lowers the apparent doping for either Se temperature. The results indicate that heat treatment in an environment including Se reduces Se vacancies in the polycrystalline lattice.

FIG. 17 shows a comparison of selenium levels in a bulk region of the absorber layer for samples of CdSe layers after a cadmium chloride heat treatment at either 440 C or 460 C. and cither with selenium vapor (right data bars) or without selenium vapor (left data bars). An increase in Se can be detected with x-ray fluorescence. The data show an increase in selenium in the CdSe layer for layers processed with selenium vapor treatment.

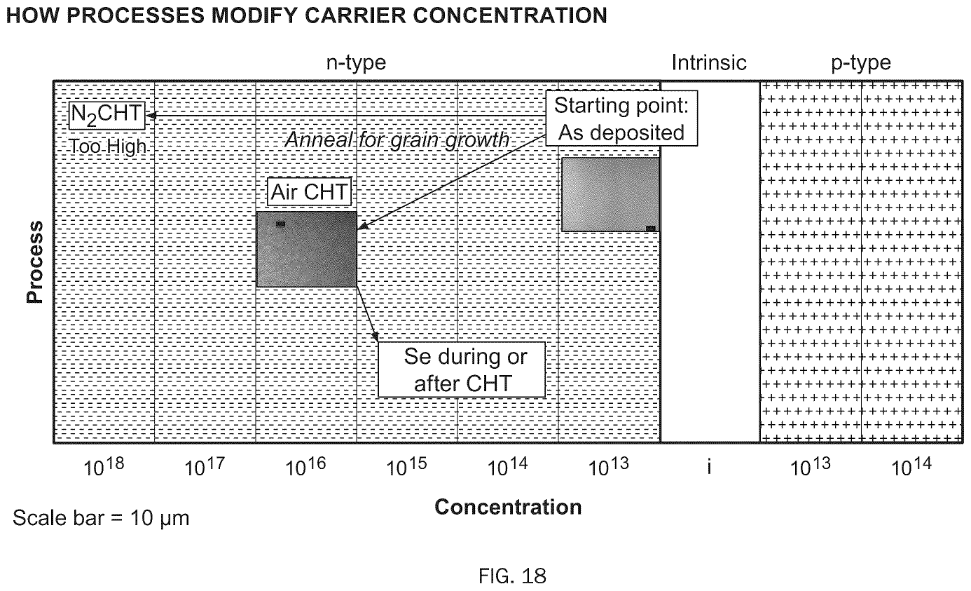

FIG. 18 illustrates changes in apparent charge carrier concentration associated with treatment processes. Annealing with cadmium chloride in a nitrogen environment can produce desired grain growth but has the detrimental effect of introducing a high number of selenium vacancies. The increase in apparent charge carrier concentration associated with the nitrogen environment is not primarily due changes in dopant concentration, but rather to an increase in selenium vacancies, and corresponding to a high apparent n-type charge carrier concentration of around 1×10¹⁸ cm⁻³. Increased selenium vacancies can lead to decreased carrier lifetimes, increased recombination rates, and decreased carrier diffusion lengths, resulting in lower overall efficiency. Providing a halogen heat treatment with oxygen, or with oxygen and selenium, can ameliorate defects and reduce selenium vacancies, this post-deposition treatment is associated with a change in apparent charge carrier concentration levels for the CdSe film to levels in a range of about 1×10¹⁶ cm⁻³.

The results indicate that an n-type CdSe absorber layer, deposited by vapor transport deposition at a temperature in a range of about 400° C. to about 490° C., with post-deposition treatment in an oxygenated and/or selenium enriched environment, produces devices with fewer defects, less recombination, and a longer lifetime for mobile charge carriers. As measured, the heat treatment of the doped devices generally increased efficiency, increased V_{OC}, increased short-circuit current density, improved fill-factor, reduced resistance, reduced shunting, and improved performance.

It should now be understood that embodiments of the present disclosure provide an n-type CdSe absorber layer and methods of making and treating the absorber layer.

According to the embodiments provided herein, a photovoltaic device can include an absorber layer and a back contact. The absorber layer can include cadmium and selenium.

A tandem photovoltaic device can include an upper submodule over a lower submodule. The upper submodule can include an absorber layer, comprising cadmium and selenium, or consisting essentially of CdSe, and a hole contact forming a p-n junction with the absorber layer. In embodiments, the absorber layer is n-type and the absorber layer has an n type carrier concentration of less than 1×10¹⁷ cm⁻³. In some embodiments, the absorber layer includes chlorine in grain boundaries at a level equal to or greater than 1×10¹³ cm⁻³ in the grain boundaries as measured by secondary-ion mass spectrometry.

A method for forming an absorber layer of a photovoltaic device can include providing a layer stack comprising a p-type layer; depositing a polycrystalline film over the p-type layer, wherein the polycrystalline film comprises cadmium and selenium, or consists essentially of CdSe. The method can include contacting an exposed surface of the polycrystalline film with a halogen compound and, optionally, an accelerant. The method can include heating the polycrystalline film in a controlled environment to form the absorber layer, wherein the controlled environment comprises oxygen, whereby the absorber layer has an n type carrier concentration of less than 1×10¹⁷ cm⁻³. In some embodiments the controlled environment includes selenium. In some embodiments the method produces the absorber layer with chlorine in grain boundaries at a level equal to or greater than 1×10¹³ in the grain boundaries as measured by secondary-ion mass spectrometry. In some embodiments the method produces the absorber layer with an average grain size of the polycrystalline film is greater than a thickness of the film.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A tandem photovoltaic device comprising an upper submodule over a lower submodule, wherein the upper submodule comprises:
an absorber layer consisting essentially of CdSe, wherein:
the absorber layer is n-type;
the absorber layer has an n type carrier concentration of less than 1×10¹⁷ cm⁻³; and
the absorber layer includes chlorine in grain boundaries at a level equal to or greater than 1×10¹³ cm⁻³ in the grain boundaries as measured by secondary-ion mass spectrometry; and
a hole contact forming a p-n junction with the absorber layer.

2-3. (canceled)

4. The tandem photovoltaic device of claim 1, wherein the absorber layer has an n type carrier concentration of less than or equal to 1×10¹⁶ cm⁻³.

5-6. (canceled)

7. The tandem photovoltaic device of claim 1, wherein the absorber layer includes a dopant comprising rubidium (Rb).

8. The tandem photovoltaic device of claim 1, wherein the absorber layer is a polycrystalline film having a thickness in a range of 0.25 μm to 2.0 μm and an average grain size in a range of 1.3 μm to 3.0 μm.

9. The tandem photovoltaic device of claim 1, wherein the absorber layer is a polycrystalline film wherein a ratio of grains having (103) orientation relative to (002) orientation is equal to or greater than 1:1000.

10. The tandem photovoltaic device of claim 1, wherein the hole contact comprises a high work function layer having a work function greater or equal to than 5 eV.

11. The tandem photovoltaic device of claim 1, wherein the hole contact comprises a layer having a p mobility to n mobility ratio of less than 2.

12. The tandem photovoltaic device of claim 1, wherein:
the hole contact comprises a p+ layer of a n+/p+ tunnel junction,
n+/p+ tunnel junction has a n+ side and a p+ side, and
the absorber layer forms the p-n junction with the p+ side of the n+/p+ tunnel junction.

13. The tandem photovoltaic device of claim 12, wherein:
the n+ side of the n+/p+ tunnel junction comprises a layer of a metal oxide doped n+, and the metal oxide comprises at least one of: SnO₂:F, ITO, Cd₂SnO₄, WO₃, MoO₃, CrO₃, or V₂O₅.

14-21. (canceled)

22. The tandem photovoltaic device of claim 12, wherein the n+ side of the n+/p+ tunnel junction comprises at least one of: GaP, BP, or ZnSe.

23-24. (canceled)

25. The tandem photovoltaic device of claim 1, wherein the hole contact comprises a p-type transparent conductive oxide.

26-27. (canceled)

28. The tandem photovoltaic device of claim 25, wherein the p-type transparent conductive oxide is doped with B, Mg, N, Sb, or any combination thereof.

29. The tandem photovoltaic device of claim 1, wherein the hole contact comprises at least one of: PTAA, PDI, CBP, TCTA, TCP, F8BT, CuAlS₂, CuAlSe₂, CuGaO₂, GeMgP₂, BP, GaP, ZnSe, TaOₓN₍₁₋ₓ₎, MoS₂, WS₂, NbS₂, VS, TaS₂, TiS₂, or a p-type alloy of Zn, S, Se, and Te.

30-45. (canceled)

46. A method for forming an absorber layer of a photovoltaic device comprising:
providing a layer stack comprising a p-type layer;
depositing a polycrystalline film over the p-type layer, wherein the polycrystalline film consists essentially of CdSe;
contacting an exposed surface of the polycrystalline film with a halogen compound and an accelerant;
heating the polycrystalline film in a controlled environment to form the absorber layer, wherein the controlled environment comprises oxygen and selenium, whereby:
the absorber layer has an n type carrier concentration of less than 1×10¹⁷ cm⁻³; and
the absorber layer includes chlorine in grain boundaries at a level equal to or greater than 1×10¹³ in the grain boundaries.

47-48. (canceled)

49. The method of claim 46, wherein the halogen compound comprises at least one of: CdCl₂, NH₄Cl, CdBr₂, CdI₂, MgCl₂, or Ba(ClO₃)₂.

50. The method of claim 46, wherein the accelerant comprises at least one of: Li, Na, K, Rb, or Cs.

51. The method of claim 46, wherein the accelerant comprises rubidium chloride.

52-53. (canceled)

54. The method of claim 46, wherein an average grain size of the polycrystalline film is in a range of 1.3 μm to 3.0 μm.

55. A method for forming a photovoltaic device comprising:
annealing an absorber layer consisting essentially of CdSe in the presence of a halogen compound, whereby a grain size of the absorber layer grows and halogen diffuses into the absorber layer; and
treating the absorber layer by heating in a controlled environment comprising Se and O₂, whereby the treating reduces Se vacancies in the absorber layer.

56. The method of claim 55, wherein the annealing step and the treating step are performed sequentially, wherein the annealing step precedes the treating step.

57-82. (canceled)
